(19) United States
(12) Patent Application Publication
(10) Pub. No.: US 2009/0252985 A1
(43) Pub. Date: Oct. 8, 2009

(54) THERMAL BARRIER COATING SYSTEM AND COATING METHODS FOR GAS TURBINE ENGINE SHROUD

(76) Inventors: Bangalore Nagaraj, West Chester, OH (US); Rachel T. Farr, Kemah, TX (US)

Correspondence Address: GENERAL ELECTRIC COMPANY, GE AVIATION, ONE NEUMANN WAY MD H17, CINCINNATI, OH, 45215, US

(21) Appl. No.: 12/129,810

(22) Filed: May 30, 2008

Related U.S. Application Data
(60) Provisional application No. 61/043,286, filed on Apr. 8, 2008.

(51) Int. Cl. B32B 3/10; B32B 5/18; C23C 16/513

(52) U.S. Cl. 428/613; 428/155; 427/448; 428/332

(57) ABSTRACT

A CMAS resistant coating system and method for a gas turbine engine component includes a thermally insulating coating having a dense vertically microcracked ceramic inner layer and a columnar-grained ceramic top layer. The inner layer may be applied by an air plasma spray technique. The top layer may be deposited by a physical vapor deposition technique. In an exemplary coating, a ratio of the thickness of the top layer to the thickness of the inner layer is greater than about 2 to 1. The layered coating may be particularly useful for the relatively thick coatings in gas turbine engine shroud applications.

### CROSS REFERENCE TO RELATED APPLICATIONS

This Application claims priority to U.S. Provisional Application Ser. No. 61/043,286, filed Apr. 8, 2008, which is herein incorporated by reference in its entirety.

### BACKGROUND OF THE INVENTION

This invention relates generally to thermal barrier coating systems used to insulate substrate materials from high temperature environments. In particular, this invention has specific application as a thermal barrier coating system for a superalloy component of a gas turbine engine.

In the art, it is known to apply a thermal barrier coating (TBC) to a substrate material to inhibit the flow of heat into the substrate. Such coatings commonly protect alloy components of gas turbine engines that are exposed to the hot combustion gas.

Ceramic thermal barrier coating materials may be applied to a metal alloy substrate by a vapor deposition process such as electron beam physical vapor deposition (EB-PVD). A ceramic layer deposited by vapor deposition may form a columnar-grained structure, wherein a plurality of individual columns of directionally solidified ceramic material are separated by small gaps extending through essentially the entire thickness of the TBC layer. One such approach is described in U.S. Pat. No. 4,405,659 to Strangman. The gaps between the various columns of material function to relieve stress in the material, thereby reducing its susceptibility to failure caused by thermal shock.

It is also known to apply a ceramic thermal barrier coating material by an air plasma spray (APS) process. Such coatings are formed by heating a gas-propelled spray of a powdered metal oxide or non-oxide material with a plasma spray torch. The spray is heated to a temperature at which the powder particles become molten. The spray of molten particles is directed against a substrate surface where they solidify upon impact to create the coating. The conventional as-deposited APS microstructure is known to be characterized by a plurality of overlapping splats of material, wherein the inter-splat boundaries may be tightly joined or may be separated by gaps resulting in some porosity. Generally, APS coatings are less expensive to apply than EB-PVD coatings. Unlike the columnar-grained structure obtained by the EB-PVD process, the inter-splat gaps in the conventional as-deposited APS microstructure tend to densify upon exposure to high temperatures.

It is also known to achieve vertically oriented gaps in a coating applied by a modified APS process. Various methods may be employed to produce the desired vertical microcracks. The so-called Dense Vertically Microcracked (“DVM”) Thermal Barrier Coatings (“TBC”) are described, for example, in U.S. Pat. Nos. 6,047,539, 5,830,586, and 5,073,433.

U.S. Pat. No. 6,716,539 to Subramanian describes a thermal barrier coating including a porous first layer of ceramic insulating material having a conventional as-deposited APS microstructure, and a relatively dense second layer of ceramic insulating material having a plurality of generally vertical gaps formed therein. The second layer may be applied by an APS process in order to provide a DVM coating layer.

A current thermal barrier coating system includes an air plasma sprayed MCrAlY bond coating with a yttria-stabilized zirconia (YSZ) TBC top coat. In particular, for shroud applications, an air plasma sprayed (APS) YSZ thermal barrier coating on a suitable bond coating represents the current state of the art system.

Despite the developments in coating technology summarized above, there remains a need in the art for improved coating systems and methods of application for metal alloy components exposed to high temperature environments in gas turbine engine components. In particular, gas turbine engine components used in desert environments may degrade due to sand related distress of thermal barrier coatings. The mechanism for such distress is believed to be caused by the penetration of molten CMAS (a relatively low-melting eutectic of calcia, magnesia, alumina and silica) that leads to spallation and then accelerated oxidation of exposed metal.

Thus, there remains a need in the art for improved thermal barrier coating systems and methods of application to address the problems associated with CMAS infiltration.

### BRIEF DESCRIPTION OF THE INVENTION

The above-mentioned need or needs may be met by exemplary embodiments which provide improved CMAS-resistant TBC coating systems for use on gas turbine engine shrouds or other applicable gas turbine engine components.

An exemplary embodiment includes a gas turbine engine component comprising a substrate and a CMAS-resistant coating system applied to at least a portion of the substrate. The exemplary coating system includes a thermally insulating coating including a columnar-grained ceramic top layer overlying a dense vertically microcracked ceramic inner layer.

An exemplary embodiment includes a CMAS-resistant coating system comprising a thermally insulating coating including a columnar-grained ceramic top layer overlying a dense vertically cracked ceramic inner layer. The dense vertically microcracked ceramic inner layer may be about 10 to 50 mils thick. The thickness of the columnar-grained ceramic top layer may be selected from about 5 to 60 mils thick, about 10 to 50 mils thick, and about 15 to 40 mils thick. The exemplary coating system includes a bond coating suitable for adhering the thermally insulating coating to a metallic substrate.

An exemplary embodiment includes a method for providing a CMAS-resistant coating system for a substrate. The exemplary method includes: providing a substrate, applying a bond coating to at least a portion of the substrate, and overlying at least a portion of the bond coating with a thermally insulating coating comprising a dense vertically microcracked ceramic inner layer and a columnar-grained ceramic top layer. The dense vertically microcracked inner layer is applied using an air plasma spray technique and the columnar-grained top layer is deposited by an electron beam physical vapor deposition technique.

An exemplary embodiment includes a coated CMAS resistant article comprising a metallic substrate, a thermally insulating coating having a thickness of from about 10 to 70 mils, and a bond coating suitable for adhering the thermally insulating coating to the metallic substrate. The thermally insulating coating is formed by depositing a thermally insulating ceramic composition onto at least a surface of the substrate by a physical vapor deposition technique to provide the coating with a columnar-grained microstructure. The thermally insulating coating provides greater resistance to CMAS infiltration than a coating of comparable thickness that is formed by applying a comparable thermally insulating ceramic composition by an air plasma spray technique to at least a portion of a comparable bond coated substrate.

### BRIEF DESCRIPTION OF THE DRAWINGS

The invention, however, may be best understood by reference to the following description taken in conjunction with the accompanying drawing figures in which:

FIG. 1 is a schematic representation of a substrate such as a turbine shroud coated with an exemplary thermal barrier coating system.

FIG. 2 depicts a thermal barrier coating having a columnar-grained microstructure indicative of an electron beam physical vapor deposition (EB-PVD) technique.

FIG. 3 depicts a thermal barrier coating having a conventional as-deposited porous microstructure indicative of a conventional air plasma spray (APS) deposition technique.

FIG. 4 depicts a thermal barrier coating having a dense vertically microcracked (DVM) microstructure indicative of a modified air plasma spray deposition technique.

FIG. 5 is a schematic representation of a substrate coated with an alternate exemplary thermal barrier coating system.

### DETAILED DESCRIPTION OF THE INVENTION

In an exemplary embodiment, an improved CMAS-resistant TBC coating system for use on shrouds or other applicable gas turbine engine component is provided. It has been found that a thermal barrier composition, deposited by EB-PVD techniques provides greater resistance to CMAS infiltration-caused TBC spallation as compared to a conventional APS technique. In broad terms, an improved coating system includes at least a two-layer YSZ TBC. A first, inner layer is applied by an APS technique and a second, top layer is deposited by a physical vapor deposition technique such as EB-PVD.

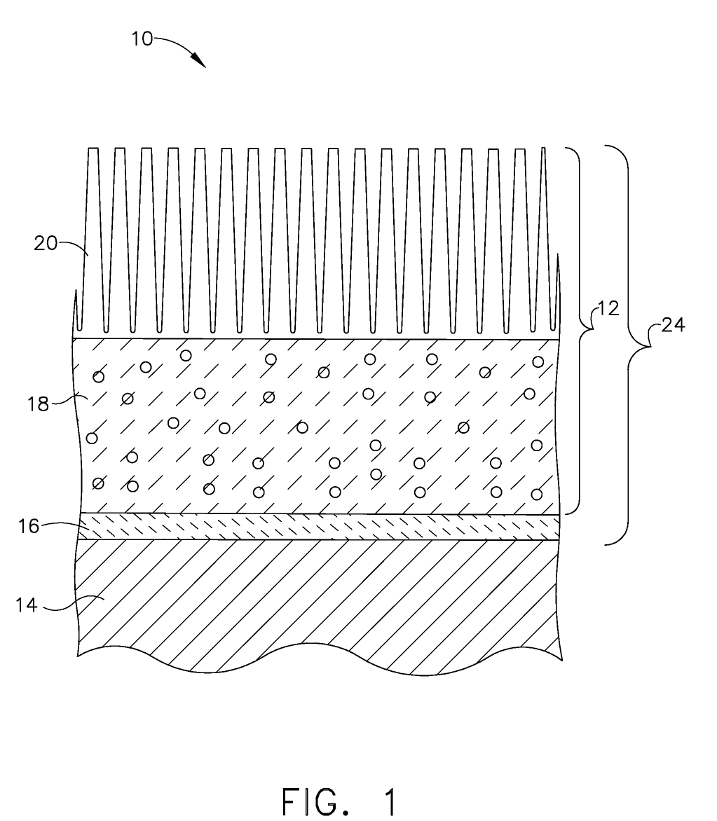

With reference to FIG. 1, an exemplary embodiment includes a gas turbine engine component 10 comprising a thermally insulating coating 12. The component 10, which may be a turbine engine shroud, includes a substrate 14. Substrate 14 may be coated with a suitable bond coating 16 for adhering the thermally insulating coating 12 to the substrate to provide a coating system 24. The term “coating system” as used herein refers to a thermally insulating coating in conjunction with a suitable bond coating. An exemplary thermally insulating coating 12 includes at least inner layer 18 and top layer 20. As explained in greater detail below, the thermally insulating coating may further include an intermediary layer or layers. Substrate 14 may comprise any material suitable for high temperature applications. Exemplary substrate materials include metal alloys and superalloys, particularly nickel base superalloys.

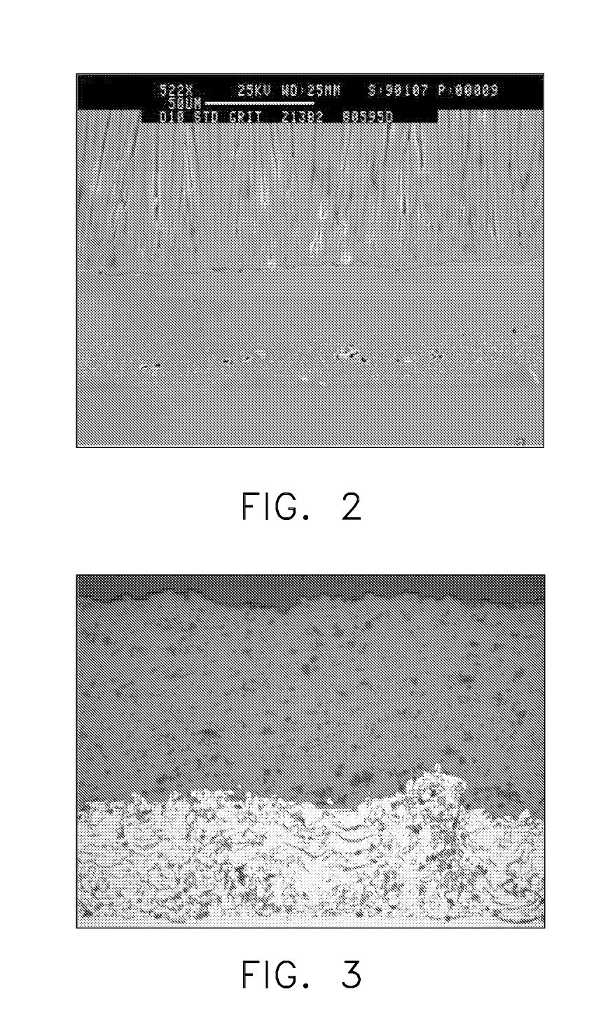

FIGS. 2-4 depict various microstructures encountered in the art. In general, the microstructure exhibited by the coating is indicative of the method of application or deposition of the coating composition. For example, FIG. 2 illustrates a coating having a fine columnar-grained microstructure. This type of microstructure is indicative of deposition of a thermal barrier coating composition using a physical vapor deposition process such as electron beam physical vapor deposition (EB-PVD). Such techniques are useful, for example, for coating turbine airfoils. In general, airfoils may include an EB-PVD coating having a thickness of from about 5 to about 10 mils.

FIG. 3 illustrates a coating having a porous microstructure indicative of application of a thermal barrier coating composition using a conventional air plasma spray (APS) technique. As described above, the coating is applied as a series of overlapping splats generating the resulting porosity. Conventional APS processes may be utilized, for example, in combustor applications having a coating thickness of from about 10 to 25 mils.

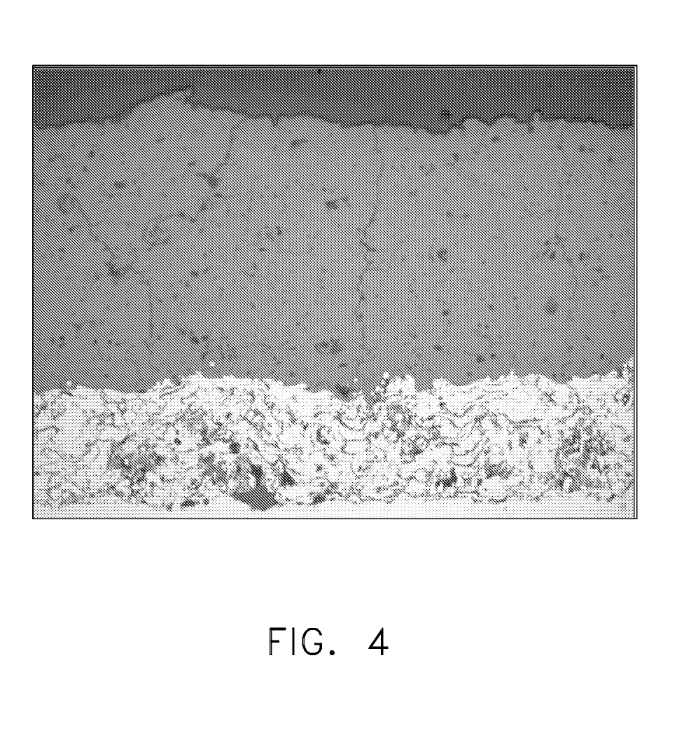

FIG. 4 depicts a coating exhibiting a so-called dense vertically microcracked (DVM) microstructure. This type of microstructure is generally less porous (more dense) than conventional APS coatings and provides some vertical gaps or cracks to improve strain tolerance. Typically, the DVM coatings for gas turbine engine shrouds have a thickness of greater than about 30 mils. The DVM microstructure may be obtained from a high density spray process, known in the art as a dense vertically cracked deposition technique.

In thermal gradient testing of 25 mil EB-PVD TBC and 25 mil APS TBC with CMAS deposited over the TBC, the EB-PVD TBC showed a two-fold improvement in life as compared to the APS TBC. Thus, it is believed that the columnar-grained microstructure obtained by PVD techniques improves the coating's resistance to CMAS infiltration. It is believed that improved resistance to CMAS infiltration may be provided by EB-PVD deposition techniques for coatings from 10 to 70 mils thick as compared to comparable APS applied coatings.

Generally, the thermal conductivity of an APS TBC is lower than an EB-PVD TBC. Thus, for thicker coatings, such as shroud applications, it may be desirable to provide a coating system utilizing both application techniques. For thicker coating applications (i.e., greater than about 15 mils), APS coatings tend toward spallation difficulties. Thus, the two-step approach is desirable. The inner layer may be applied using an APS technique (conventional or modified) and a top layer may be deposited by a physical vapor deposition process. In applications where the coating thickness is thinner (less than about 70 mils) it may be feasible to use a PVD TBC as a one step coating for improved resistance to CMAS infiltration.

In an exemplary embodiment, a suitable bond coating is applied to a substrate. A suitable bond coating may be an overlay MCrAlY coating or a diffusion coating such as a simple aluminide or a platinum aluminide coating. A thermally insulating ceramic composition, such as yttria-stabilized zirconia, is applied to the bond coating using an APS technique to provide an inner layer having a thickness of from about 10 to about 50 mils. The inner layer may exhibit a splat-like, conventional as-applied APS microstructure or a DVM microstructure, depending on the particular application technique. In an exemplary embodiment, the surface of the inner APS-applied layer is polished (i.e., grit blasted, machined, or otherwise subjected to an additional process step) to achieve a desired surface finish. Thereafter, an EB-PVD deposition technique is used to deposit a top layer of the same or different thermally insulating ceramic composition. The top layer may have a thickness of from about 5 to about 60 mils. In an exemplary embodiment, the inner layer and outer layer are applied so that the ratio of the thickness of the outer layer to the inner layer is greater than about 2 to 1.

In an exemplary embodiment, there is provided a turbine engine component having a multi-layered thermal barrier coating system to resist CMAS infiltration. An exemplary embodiment includes a turbine engine component which broadly comprises a substrate, a bond coating overlying at least a surface of the substrate, an inner thermal barrier layer exhibiting a first microstructure indicative of a first application technique, and a second thermal barrier layer exhibiting a second microstructure indicative of a second application technique. The inner thermal barrier layer is associated with a first coating thickness. The second thermal barrier layer is associated with a second coating thickness.

In an exemplary embodiment, there is provided a turbine engine component having a thermal barrier coating in need of repair. The thermal barrier coating may exhibit a microstructure indicative of a conventional APS application process. Alternately, the thermal barrier coating may exhibit a DVM microstructure indicative of a modified APS application process. In any event, the thermal barrier coating may be repaired by EB-PVD application of a thermally insulating composition onto the previously-applied coating.

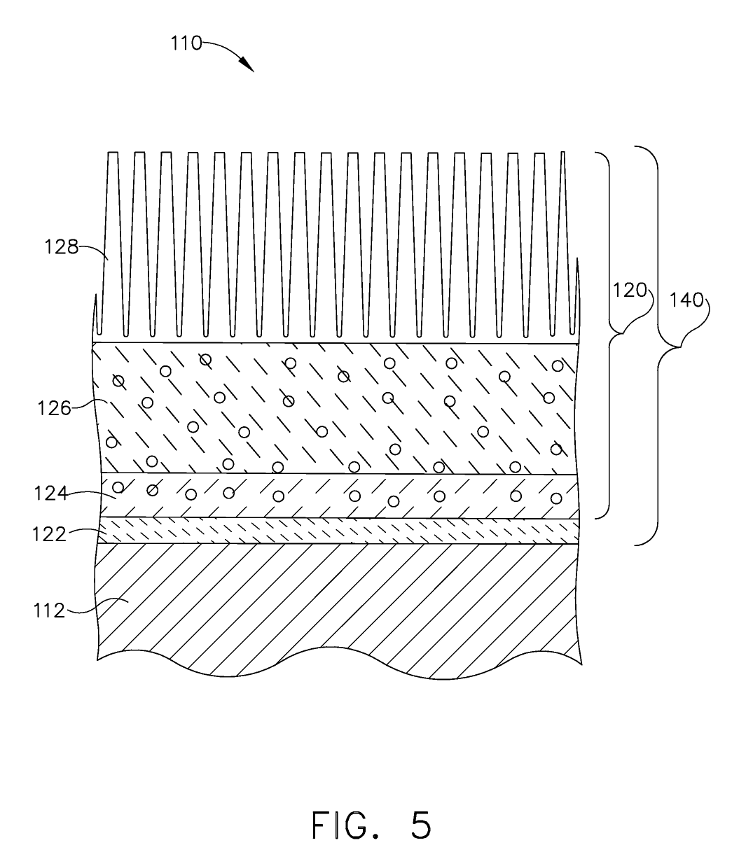

With reference to FIG. 5, in an exemplary embodiment, there is provided a component 110 including substrate 112 and a multi-layer coating system 140. An exemplary multi-layer coating system includes a bond coating 122 and a thermally insulating coating 120. In an exemplary embodiment, thermally insulating coating 120 includes an inner layer 124 comprising a yttria stabilized zirconia composition (e.g., 7YSZ) having a pre-selected porosity and microstructure, an intermediate layer 126 comprising a thermally insulating composition having a lower thermal conductivity than conventional 7YSZ (e.g., zirconia containing oxides of yttrium, ytterbium, and/or gadolinium), and a top layer 128 comprising a thermally insulating composition exhibiting a columnar microstructure indicative of EB-PVD deposition. In an exemplary embodiment, the inner layer 124 and the top layer 128 may be formed from a similar thermally insulating composition (e.g., 7YSZ) and the intermediate layer 126 may be formed of a composition having a lower thermal conductivity.

In an exemplary embodiment, there is provided a thermal barrier coating system having an inner layer comprising a thermal barrier composition having a microstructure indicative of an APS deposition technique, either conventional or modified to provide a DVM coating. The exemplary coating system includes a top layer comprising a thermal barrier composition and exhibiting a columnar microstructure indicative of PVD deposition. The top layer has a thickness of from about 15 to about 60 mils. The ratio of the thickness of the top layer to the inner layer is greater than 2 to 1. A DVM inner layer may be characterized by a porosity of from about 85 to about 95% of the theoretical density. Such an inner layer is more robust than a PVD coating and is thus more amenable to hole drilling.

In an exemplary embodiment, a process for providing a thermal barrier coating is provided. The inner TBC layer is applied by conventional APS techniques to obtain a porous splat-like microstructure or by a modified APS technique to obtain a less porous DVM microstructure, as discussed above. The outer TBC layer is deposited using EB-PVD deposition. For a relatively thick layer (about 15 to about 60 mils) the pressure and ingot feed rate are increased so that the deposition rate is up to 80% higher than EB-PVD deposition rates used, for example, to coat gas turbine engine airfoils where the thickness is usually in the range of 5 to 10 mils.

In an exemplary embodiment, the inner layer has a DVM microstructure. In an exemplary process, prior to deposition of the outer TBC layer, the interface surface is ground and/or machined or otherwise polished to a surface roughness of approximately 40 to about 140 microinches. In an exemplary process, the inner layer and top layer are applied so that the ratio of the thickness of the outer layer to the inner layer is greater than about 2 to 1.

In an exemplary embodiment, the bond coating may be a “strengthened bond coating.” For example, U.S. Pat. No. 5,236,745 discloses a strengthened nickel base overlay bond coating with overaluminide layer which is utilized under the thermal barrier coating to provide improved protection at high temperatures to engine components. The nominal composition of this nickel base overlay bond coating, in weight percent, is 18 Cr, 6.5 Al, 10 Co, 6 Ta, 2 Re, 0.5 Hf, 0.3 Y, 1 Si, 0.015 Zr, 0.06 C, 0.015 B, with the balance Ni and incidental impurities. The strengthened bond coating provides improved oxidation resistance, desirable surface characteristics, and crack resistance.

For exemplary embodiments including an inner layer deposited by an air plasma spray technique (conventional or modified DVM technique) the bond coating should have a rough surface for desired adhesion at the bond coating/inner layer interface. However, the surface of the air plasma sprayed layer should be smooth at the interface between the air plasma sprayed layer and the layer deposited by EB-PVD to promote regularity in the columnar microstructure. For exemplary embodiments wherein the thermally insulating coating includes only the EB-PVD columnar-grained layer (i.e., no air plasma sprayed inner layer), the bond coating should have a smooth surface.

Especially for applications requiring relatively thick thermally insulating coatings (e.g., gas turbine engine shrouds) the problem of spallation of APS applied coatings may be reduced by providing a layered coating system. An exemplary layered system includes an inner layer having a conventional APS as-deposited microstructure or a dense vertically microcracked microstructure and a top layer having a columnar-grained microstructure indicative of a physical vapor deposition technique. Further, the top layer (columnar grained microstructure) improves resistance to CMAS. Other exemplary embodiments may include a EB-PVD columnar-grained thermally insulating coating deposited onto at least a portion of the bond coating. Thus, exemplary embodiments disclosed herein provide a thermal barrier coating system, coated article, and methods of coating an article having improved resistance to CMAS infiltration.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A turbine engine component comprising:
a substrate; and
a CMAS resistant coating system applied to at least a portion of the substrate, wherein the coating system includes a thermally insulating coating including a columnar-grained ceramic top layer overlying a dense vertically microcracked (DVM) ceramic inner layer.

2. The turbine engine component according to claim 1, wherein the thermal barrier coating system further comprises a bond coating adhering the thermally insulating coating to the substrate.

3. The turbine engine component according to claim 1 wherein the dense vertically microcracked ceramic inner layer is about 10 to 50 mils thick.

4. The turbine engine component according to claim 3 wherein a thickness of the columnar-grained ceramic top layer is selected from about 5 to 60 mils thick, about 10 to 50 mils thick, and about 15 to 40 mils thick.

5. The turbine engine component according to claim 1 wherein the turbine engine component is a shroud, and wherein the dense vertically microcracked ceramic inner layer is at least about 30 mils thick and a thickness of the columnar-grained ceramic top layer is selected from about 5 to 60 mils thick, about 10 to 50 mils thick, and about 15 to 40 mils thick.

6. The turbine engine component according to claim 2 wherein the bond coating is selected from a MCrAlY coating, an aluminide coating, and a platinum aluminide coating.

7. The turbine engine component according to claim 2 wherein the bond coating is a strengthened nickel base overlay bond coating.

8. The turbine engine component according to claim 1 wherein a ratio of a thickness of the columnar-grained ceramic top layer to a thickness of the dense vertically microcracked ceramic inner layer is greater than about 2 to 1.

9. The turbine engine component according to claim 2 wherein:
the substrate comprises a nickel-base superalloy;
the bond coating is selected from a MCrAlY coating, an aluminide coating, and a platinum aluminide coating;
the dense vertically microcracked ceramic inner layer comprises the yttria-stabilized zirconia composition deposited by an air plasma spray technique,
the columnar-grained ceramic top layer comprises a yttria-stabilized zirconia composition deposited by an electron beam physical vapor deposition technique; and
wherein a ratio of a thickness of the columnar-grained ceramic top layer to a thickness of the dense vertically cracked ceramic inner layer is greater than about 2 to 1.

10. A CMAS resistant coating system comprising:
a thermally insulating coating including a columnar-grained ceramic top layer overlying a dense vertically microcracked (DVM) ceramic inner layer, wherein the dense vertically microcracked ceramic inner layer is about 10 to 50 mils thick and a thickness of the columnar-grained ceramic top layer is selected from about 5 to 60 mils thick, about 10 to 50 mils thick, and about 15 to 40 mils thick; and
a bond coating suitable for adhering the thermally insulating coating to a metallic substrate.

11. The CMAS resistant coating system according to claim 10 wherein the dense vertically microcracked ceramic inner layer is applied by an air plasma spray technique and the columnar-grained ceramic top layer is deposited by an electron beam physical vapor deposition technique.

12. A method for providing a CMAS resistant coating system for a substrate comprising:
providing a substrate;
applying a bond coating to at least a portion of the substrate;
overlying at least a portion of the bond coating with a thermally insulating coating comprising a dense vertically microcracked ceramic inner layer and a columnar-grained ceramic top layer, wherein the dense vertically microcracked inner layer is applied using an air plasma spray technique and the columnar-grained top layer is deposited by an electron beam physical vapor deposition technique.

13. The method for providing a CMAS resistant coating system for a substrate according to claim 12 wherein the inner layer is applied to a first thickness and the top layer is deposited to a second thickness and wherein a ratio of the second thickness of the top layer to the first thickness of the inner layer is greater than about 2 to 1.

14. The method for providing a CMAS resistant coating system for a substrate according to claim 12 further including polishing the inner layer prior to deposition of the top layer.

15. The method for providing a CMAS resistant coating system for a substrate according to claim 12 wherein providing a substrate includes providing at least one of a gas turbine engine component having a pre-existing coating in need of repair, and a new make gas turbine engine component.

16. The method for providing a CMAS resistant coating system for a substrate according to claim 15 wherein the substrate includes the gas turbine engine component having the pre-existing coating in need of repair.

17. A CMAS resistant coated article comprising:
a metallic substrate;
a bond coating disposed on at least a portion of the substrate; and
a thermally insulating coating overlying at least a portion of the bond coating having a thickness of from about 10 to 70 mils;
wherein the thermally insulating coating is formed by depositing a thermally insulating ceramic composition onto the bond coating by a physical vapor deposition technique to provide the coating with a columnar-grained microstructure; and
wherein the thermally insulating coating provides greater resistance to CMAS infiltration than a thermally insulating coating of comparable thickness being formed by applying a comparable thermally insulating ceramic composition to at least a portion of a comparable bond coated substrate by an air plasma spray technique.
